(19) United States
(12) Patent Application Publication
(10) Pub. No.: US 2019/0339309 A1
(43) Pub. Date: Nov. 7, 2019

(54) SWITCH-MODE POWER SUPPLY AND VOLTAGE SAMPLING CIRCUIT THEREOF

(71) Applicant: BYD COMPANY LIMITED, Shenzhen (CN)

(72) Inventors: Xingfu JIANG, Shenzhen (CN); Wenqing WANG, Shenzhen (CN)

(73) Assignee: BYD COMPANY LIMITED, Shenzhen (CN)

(21) Appl. No.: 16/474,975

(22) PCT Filed: Dec. 20, 2017
(86) PCT No.: PCT/CN2017/117396

§ 371 Date: Jun. 28, 2019

(30) Foreign Application Priority Data
Dec. 29, 2016 (CN) 201611247084.4

(51) Int. Cl. G01R 19/25; G01R 19/18; H02M 3/335

(52) U.S. Cl. CPC G01R 19/2503; H02M 3/33523; G01R 19/18

(57) ABSTRACT

A circuit comprises: a sampling and holding circuit and a control circuit. The sampling and holding circuit is used for sampling the voltage of a voltage sampling point in a sampling stage and holding the sampling voltage of the sampling output end after the sampling stage is ended. The control circuit is used for controlling the sampling and holding circuit to enter the sampling stage when judging that the voltage of the voltage sampling point is in a sampling voltage segment according to the voltage of the voltage sampling point, and controlling the sampling stage of the sampling and holding circuit to be ended when judging that the voltage of the voltage sampling point is in a voltage inflection point according to the voltage of the voltage sampling point and the sampling voltage of the sampling output end.

### CROSS-REFERENCE TO RELATED APPLICATIONS

This application is the U.S. national phase entry of PCT Application No. PCT/CN2017/117396, filed Dec. 20, 2017, which claims priority to and benefits of Chinese Patent Application No. 201611247084.4, filed with the State Intellectual Property Office of P. R. China on Dec. 29, 2016. The entire contents of the above-referenced applications are incorporated herein by reference.

### FIELD

The present disclosure relates to the technical field of switch power supplies, and particularly relates to a voltage sampling circuit and a switch power supply with the voltage sampling circuit.

### BACKGROUND

Due to the advantages of small volume, high efficiency, heavy current and the like, switch power supplies are widely applied to power solutions such as mobile phone chargers and adapters. In the related technologies, a voltage sampling circuit of a switch power supply usually samples the change of the voltage of a feedback coil by means of a voltage feedback pin, and the working frequency and switching-on duty ratio of a power switch tube are controlled according to the sampled voltage value so as to adjust the output voltage of a secondary coil.

However, the related technologies have the defects that the voltage of the voltage feedback pin is influenced by the load magnitude, then sampled voltage value is changed accordingly, and the magnitude of the output voltage cannot be accurately expressed, so that the output voltage of the secondary coil is difficult to keep stable, and the constant voltage precision of the switch power supply is reduced.

Therefore, the related technologies need to be improved.

### SUMMARY

An objective of the present disclosure is to at least resolve one of the technical problems in the related art to some extent. Therefore, the present disclosure is directed to a voltage sampling circuit. The circuit can increase the constant voltage precision of the switch power supply.

Another objective of the present disclosure is to provide a switch power supply.

In order to achieve the above objectives, the voltage sampling circuit provided by embodiments of one aspect of the present disclosure comprises: a sampling and holding circuit, wherein the sampling and holding circuit includes a sampling input end, a sampling output end, and a sampling control end, the sampling input end is connected with a voltage sampling point, and the sampling and holding circuit is configured to sample a voltage of the voltage sampling point in a sampling stage so as to enable a sampling voltage of the sampling output end to follow the voltage of the voltage sampling point, and holding the sampling voltage of the sampling output end after the sampling stage is ended; and a controller, wherein the controller is respectively connected with the voltage sampling point and the control end and the sampling output end of the sampling and holding circuit, and the controller is configured to control the sampling and holding circuit to enter the sampling stage when determining that the voltage of the voltage sampling point is in a sampling voltage segment according to the voltage of the voltage sampling point, and controlling the sampling stage of the sampling and holding circuit to be ended when determining that the voltage of the voltage sampling point is in a voltage inflection point according to the voltage of the voltage sampling point and the sampling voltage of the sampling output end, so as to enable the sampling voltage of the sampling output end to be held at the voltage corresponding to the voltage inflection point.

According to the voltage sampling circuit provided by the embodiment of the present disclosure, the controller controls the sampling and holding circuit to enter the sampling stage when the voltage of the voltage sampling point is in a sampling voltage segment so as to enable the sampling voltage of the sampling output end to follow the voltage of the voltage sampling point, and controls the sampling stage of the sampling and holding circuit to be ended when the voltage of the voltage sampling point is in the voltage inflection point so as to enable the sampling voltage of the sampling output end to be held at the voltage corresponding to the voltage inflection point. Therefore, by sampling the voltage of the voltage inflection point, the magnitude of the output voltage can be accurately reflected, the influence on the sampling voltage caused by the load change of the switch power supply can be avoided, the stability and accuracy of a control system are improved, the constant voltage precision of the output voltage of the switch power supply is increased, and the user experience is promoted.

In order to achieve the above objectives, the switch power supply provided by embodiments of another aspect of the present disclosure includes the voltage sampling circuit.

According to the switch power supply provided by the embodiment of the present disclosure, by sampling the voltage of the voltage inflection point by means of the voltage sampling circuit, the magnitude of the output voltage can be accurately reflected, the influence on the sampling voltage caused by the load change of the switch power supply can be avoided, the stability and accuracy of the control system are improved, the constant voltage precision of the output voltage of the switch power supply is increased, and the user experience is promoted.

### BRIEF DESCRIPTION OF THE DRAWINGS

FIG. 1 is a waveform diagram of a voltage sampling circuit in related technologies;

FIG. 2 is a block diagram of a voltage sampling circuit according to an embodiment of the present disclosure;

FIG. 3 is a waveform diagram of a voltage sampling circuit according to a specific embodiment of the present disclosure;

FIG. 4 is a schematic circuit diagram of a voltage sampling circuit according to a specific embodiment of the present disclosure;

FIG. 5 is a block diagram of a switch power supply according to an embodiment of the present disclosure;

FIG. 6 is a schematic circuit diagram of a switch power supply according to a specific embodiment of the present disclosure; and

FIG. 7 is a block diagram of a power control chip of the switch power supply as shown in FIG. 6.

### REFERENCE NUMERALS OF THE ACCOMPANYING DRAWING:

sampling and holding circuit 10; controller 20; trigger 201; first control unit 202; second control unit 203; first comparator CMP 1; second comparator CMP2; delay unit 210; sampling and holding unit 101; switch unit 102; trigger unit 103; first resistor R1; first capacitor C1; second resistor R2; second capacitor C2; first MOS transistor MOS1; second MOS transistor MOS2; leading edge blanking circuit 110.

### DETAILED DESCRIPTION

The following describes in detail embodiments of the present disclosure. Examples of the embodiments are shown in the accompanying drawings, where reference signs that are the same or similar from beginning to end represent same or similar components or components that have same or similar functions. The following embodiments described with reference to the accompanying drawings are exemplary, and are intended to describe the present disclosure and cannot be construed as a limitation to the present disclosure.

For convenience of understanding, the working principle of the voltage sampling circuit in the related technologies is briefly introduced firstly.

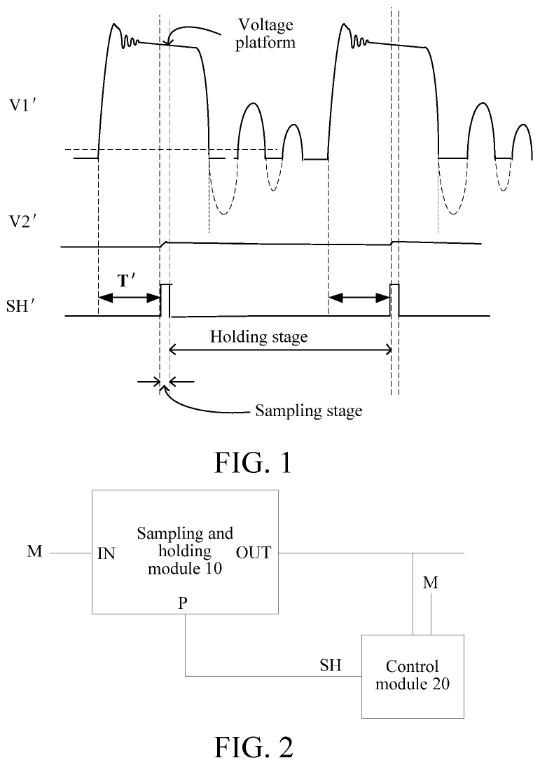

In the related technologies, the voltage sampling circuit performs filtering processing by means of RC to filter out the high-frequency interference in the waveform of the voltage V1′ of the voltage sampling point. When the voltage V1′ of the voltage sampling point rises and exceeds a preset threshold value (such as 0.1V), an output signal of a comparator of the voltage sampling circuit jumps from a low level to a high level. Because the waveform of the voltage V1′ of the voltage sampling point has resonance fluctuation at the initial stage, the output signal of the comparator is delayed for a preset delay time T′ by means of a delay circuit so as to prevent the voltage of a resonance fluctuation region from being sampled. After the output signal of the comparator is delayed for the preset delay time T′, the voltage of the middle segment of a voltage platform of the voltage V1′ of the voltage sampling point can be sampled, and the sampled voltage is closer to the average value of the voltage V1′ of the voltage sampling point. Further, a leading edge blanking (LEB) module generates a PWM signal SH′ with a tiny pulse according to the delayed output signal, and the PWM signal SH′ controls a transmission gate TR; when the PWM signal SH′ is a high level, the transmission gate TR is switched on, and the voltage sampling circuit enters a sampling stage so as to acquire the current voltage value; and when the PWM signal SH′ is a low level, the transmission gate TR is switched off, the sampling stage of the voltage sampling circuit is ended, and the voltage sampling circuit enters a holding stage. The sequential logic of the whole sampling process is as shown in FIG. 1.

As shown in FIG. 1, in a period, the voltage platform of the waveform of the voltage V1′ of the voltage sampling point is not completely equal but has a downtrend, therefore, when the preset delay times of the delay circuit are different, the voltage V1′ sampled by the voltage sampling circuit may be different. Furthermore, because the voltage platform time of the voltage sampling point actually corresponds to the degaussing time of a secondary winding, when the loads of a switch power supply are different, the voltage platform time of the voltage sampling point is changed. When the load of the switch power supply is heavier, the voltage platform time of the voltage sampling point is longer; and when the load of the switch power supply is lighter, the voltage platform time of the voltage sampling point is shorter. Therefore, when the loads of the switch power supply are different, after the preset delay time is delayed by the delay circuit, the voltage of the voltage sampling point may not accurately represent the magnitude of the output voltage, the sampling voltage V2′ output by the voltage sampling circuit is not accurate, and the sampling voltage V2′ received by an error amplifier has an offset, so that the control of a power control chip is invalid, the voltage output by a system has an offset, i.e., the voltage output by the switch power supply is not the preset voltage value, and then, the constant voltage precision of the switch power supply is reduced.

Based on the above, the embodiments of the present disclosure provide a switch power supply and a voltage sampling circuit thereof.

The switch power supply and the voltage sampling circuit thereof provided by the embodiments of the present disclosure are described below with reference to the accompanying drawings.

FIG. 2 is a block diagram of a voltage sampling circuit according to an embodiment of the present disclosure. As shown in FIG. 2, the voltage sampling circuit comprises: a sampling and holding circuit 10 and a controller 20. The voltage sampling circuit can be arranged on the power control chip of the switch power supply.

The sampling and holding circuit 10 includes a sampling input end IN, a sampling output end OUT, and a sampling control end P, the sampling input end IN is connected with a voltage sampling point M, and the sampling and holding circuit 10 is used for sampling the voltage V1 of the voltage sampling point M in a sampling stage so as to enable the sampling voltage V2 of the sampling output end to follow the voltage V1 of the voltage sampling point M, and holding the sampling voltage V2 of the sampling output end after the sampling stage is ended. The controller 20 is respectively connected with the voltage sampling point M and the sampling control end P and the sampling output end OUT of the sampling and holding circuit 10, and the controller 20 is used for controlling the sampling and holding circuit 10 to enter the sampling stage when judging that the voltage V1 of the voltage sampling point M is in a sampling voltage segment according to the voltage V1 of the voltage sampling point M, and controlling the sampling stage of the sampling and holding circuit 10 to be ended when judging that the voltage V1 of the voltage sampling point M is in a voltage inflection point according to the voltage V1 of the voltage sampling point M and the sampling voltage V2 of the sampling output end, so as to enable the sampling voltage V2 of the sampling output end to be held at the voltage corresponding to the voltage inflection point.

In other words, the controller 20 receives the voltage V1 of the voltage sampling point M and judges whether the voltage V1 of the voltage sampling point M is in a sampling voltage segment or not. When the voltage V1 of the voltage sampling point M is in the sampling voltage segment, the controller 20 outputs a switching-on control signal SH (such as a high level) to the sampling control end P of the sampling and holding circuit 10, the sampling and holding circuit 10 enters the sampling stage when receiving the switching-on control signal SH, and at this time, the sampling and holding circuit 10 samples the voltage V1 of the voltage sampling point M so as to enable the sampling voltage V2 of the sampling output end to follow the voltage V1 of the voltage sampling point M. When the voltage V1 of the voltage sampling point M is changed to a voltage inflection point, the controller 20 outputs a switching-off control signal SH (such as a low level) to the sampling control end P of the sampling and holding circuit 10, the sampling and holding circuit 10 ends the sampling stage and enters the holding stage when receiving the switching-off control signal SH, and at this time, the sampling voltage V2 of the sampling output end is held at the voltage corresponding to the voltage inflection point.

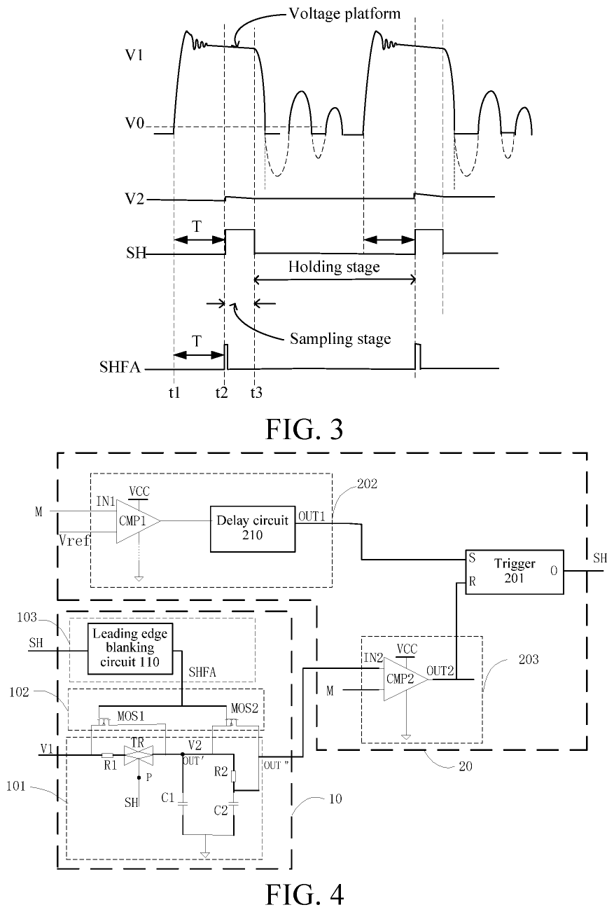

It should be noted that in conjunction with the embodiment as shown in FIG. 6, the voltage sampling point M can be a voltage feedback end Q of the feedback coil in the switch power supply, namely the voltage feedback pin VFB (voltage feed back) of the power control chip as shown in FIG. 6. Because the voltage platform time of the voltage sampling point M actually corresponds to the degaussing time of the secondary winding, after the degaussing of the secondary coil is finished, the current flowing through the secondary coil is 0; at this time, the secondary coil does not generate voltage drop, the outlet line of the secondary coil also does not generate voltage drop, and the feedback coil can accurately map the output voltage of the secondary coil; and at this time, if the voltage sampling circuit samples the voltage of the voltage feedback pin VFB of the feedback coil, the voltage of the voltage sampling point M can accurately map the magnitude of the output voltage. As shown in FIG. 3, at the time t3, after the degaussing of the secondary coil is finished, the voltage of the voltage feedback pin VFB starts to drop, that is, the waveform of the voltage V1 of the voltage sampling point M has a voltage inflection point. Therefore, regardless of the voltage platform time of the voltage sampling point M and regardless of a light load or a heavy load, the finally sampled voltage is the voltage corresponding to the voltage inflection point and can accurately map the magnitude of the output voltage of the secondary coil.

Therefore, the sampling and holding circuit 10 can sample the voltage corresponding to the voltage inflection point, takes the voltage corresponding to the voltage inflection point as the final sampling voltage to be output to the error amplifier, and adjusts the control signal output by the power control chip according to the sampling voltage so as to adjust the working frequency and switching-on duty ratio of the power switch tube to keep the output voltage of the secondary coil stable, so that the influence on the sampling voltage caused by the load change of the switch power supply can be avoided, the stability and accuracy of the control system are improved, the constant voltage precision of the output voltage of the switch power supply is increased, and the user experience is promoted.

The circuit structure and the working principle of the voltage sampling circuit according to the embodiments of the present disclosure are specifically described below with reference to FIG. 3 and FIG. 4.

According to an embodiment of the present disclosure, as shown in FIG. 4, the controller 20 comprises: a trigger 201, a first control unit 202, and a second control unit 203.

The trigger 201 includes a setting end S, a resetting end R, and an output end O, and the output end O of the trigger 201 is connected with the sampling control end P of the sampling and holding circuit 10; the input end IN1 of the first control unit 202 is connected with the voltage sampling point M, the output end OUT1 of the first control unit 202 is connected with the setting end S of the trigger 201, and the first control unit 202 is used for controlling the setting of the trigger 201 to control the sampling and holding circuit 10 to enter the sampling stage when judging that the voltage V1 of the voltage sampling point M is in a sampling voltage segment; and the input end IN2 of the second control unit 203 is respectively connected with the voltage sampling point M and the sampling output end, the output end OUT2 of the second control unit 203 is connected with the resetting end R of the trigger 201, and the second control unit 203 is used for controlling the resetting of the trigger 201 to control the sampling stage of the sampling and holding circuit 10 to be ended when judging that the voltage of the voltage sampling point M is in a voltage inflection point.

Specifically, when the voltage V1 of the voltage sampling point M is in the sampling voltage segment, the output end OUT1 of the first control unit 202 outputs a sampling signal (such as a high level) to the setting end S of the trigger 201 so as to control the setting of the trigger 201, and the trigger 201 outputs a switching-on control signal SH to the sampling control end P of the sampling and holding circuit 10 so as to control the sampling and holding circuit 10 to enter the sampling stage; and when the voltage of the voltage sampling point M is in the voltage inflection point, the output end OUT2 of the second control unit 203 outputs a sampling end signal (such as a high level) to the resetting end R of the trigger 201 so as to control the resetting of the trigger 201, and the trigger 201 outputs a switching-off control signal SH to the sampling control end P of the sampling and holding circuit 10 so as to control the sampling stage of the sampling and holding circuit 10 to be ended to enter a holding stage.

It should be noted that the sampling voltage segment can refer to the middle segment of a voltage platform of the voltage V1 of the voltage sampling point M. In the embodiment of the present disclosure, the voltage V1 of the voltage sampling point M is compared with a preset voltage V0, and after the voltage V1 of the voltage sampling point M is greater than the preset voltage V0, the preset delay time is delayed to judge that the voltage V1 of the voltage sampling point M is in the sampling voltage segment, namely the middle segment of the voltage platform.

According to an embodiment of the present disclosure, as shown in FIG. 4, the first control unit 202 comprises: a first comparator CMP1 and a delay unit 210, wherein the first input end of the first comparator CMP1 is connected with the voltage sampling point M, the second input end of the first comparator CMP1 is connected with a preset voltage supply end Vref, and the first comparator CMP1 is used for outputting a sampling signal when the voltage V1 of the voltage sampling point M is greater than the preset voltage V0 (for example, supplied by Vref); and one end of the delay unit 210 is connected with the output end of the first comparator CMP 1, the other end of the delay unit 210 is connected with the setting end S of the trigger 201, and the delay unit 210 is used for delaying the sampling signal for the preset delay time T and then outputting the sampling signal to the trigger 201 so as to control the setting of the trigger 201. Furthermore, the power end of the first comparator CMP1 is connected with a preset power supply VCC, and the grounding end of the first comparator CMP1 is grounded.

Specifically, the preset voltage V0 supplied by the preset voltage supply end Vref can be 0.1V; when the voltage V1 of the voltage sampling point M is less than or equal to 0.1V, the first comparator CMP1 outputs a first sampling signal (such as a low level); and when the voltage V1 of the voltage sampling point M is greater than 0.1V, the output of the first comparator CMP1 is inverted to output a second sampling signal (such as a high level). The delay circuit 210 delays the sampling signal output by the first comparator CMP1 for the preset delay time T and then outputs the sampling signal to the setting end S of the trigger 201, so that after the first comparator CMP1 outputs a high level, the preset delay time T is delayed to control the setting of the trigger 201, and the sampling and holding circuit 10 enters the sampling stage.

It should be noted that as shown in FIG. 3, because the voltage V1 of the voltage sampling point M has oscillation fluctuation at the initial stage in one period, the delay circuit 210 delays the sampling signal for the preset delay time T so as to prevent the sampling and holding circuit 10 from sampling the voltage with larger interference at the initial stage of the voltage platform.

According to an embodiment of the present disclosure, as shown in FIG. 4, the second control unit 203 comprises: a second comparator CMP2, wherein the first input end of the second comparator CMP2 is connected with the sampling output end, the second input end of the second comparator CMP2 is connected with the voltage sampling point M, the output end of the second comparator CMP2 is connected with the resetting end R of the trigger 201, and the second comparator CMP2 is used for outputting a sampling end signal to the trigger 201 so as to control the resetting of the trigger 201 when the difference value between the sampling voltage V2 output by the sampling output end and the voltage V1 of the voltage sampling point M is greater than a preset threshold value. Furthermore, the power end of the second comparator CMP2 is connected with the preset power supply VCC, and the grounding end of the second comparator CMP2 is grounded.

According to a specific embodiment of the present disclosure, the second comparator CMP2 can be a comparator with a tiny mismatch at the input end. In other words, when the difference value between the first input end and the second input end of the second comparator CMP2 is smaller, the level output by the second comparator CMP2 is not inverted.

Specifically, in the voltage sampling stage, the change of the sampling voltage V2 output by the sampling output end is later than the change of the voltage V1 of the voltage sampling point M. As shown in FIG. 3, at the middle segment of the voltage platform of the voltage sampling point M, the change of the voltage V1 of the voltage sampling point M is slower, at this time, the difference value between the sampling voltage V2 output by the sampling output end and the voltage V1 of the voltage sampling point M is less than the preset threshold value, i.e., the voltage difference value between the first input end and the second input end of the second comparator CMP2 is less than the preset threshold value, the second comparator CMP2 outputs a first sampling end signal (such as a low level) to the resetting end R of the trigger 201, and the trigger 201 holds the setting so as to continue to output a high level. As shown in FIG. 3, when the voltage of the voltage sampling point M is in a voltage inflection point, the voltage V1 of the voltage sampling point M suddenly drops, and the change of the sampling voltage V2 output by the sampling output end is later than the change of the voltage V1 of the voltage sampling point M, so that the difference value between the sampling voltage V2 output by the sampling output end and the voltage V1 of the voltage sampling point M is greater than the preset threshold value, i.e., the voltage difference value between the first input end and the second input end of the second comparator CMP2 is greater than the preset threshold value, the second comparator CMP2 outputs a second sampling end signal (such as a high level) to the resetting end R of the trigger 201, and the trigger 201 resets to output a low level.

According to an embodiment of the present disclosure, as shown in FIG. 4, the sampling and holding circuit 10 comprises: a sampling and holding unit 101, a switch unit 102, and a trigger unit 103.

The sampling and holding unit 101 is respectively connected with the voltage sampling point M and the controller 20, the sampling and holding unit 101 comprises a transmission gate TR, and the controller 20 controls the sampling and holding circuit 10 to enter the sampling stage by controlling the transmission gate TR to be switched on, and controls the sampling stage to be ended by controlling the transmission gate TR to be switched off; the switch unit 102 is connected with the sampling and holding unit 101 in parallel; and the trigger unit 103 is respectively connected with the controller 20 and the switch unit 102, and the trigger unit 103 is used for generating a trigger signal when the sampling and holding circuit 10 enters the sampling stage to trigger the switch unit 102 to be switched on for a preset time, so as to enable the output end of the sampling and holding circuit 10 to firstly follow the voltage of the voltage sampling point M by means of the switch unit 102 and then follow the voltage of the voltage sampling point M by means of the sampling and holding unit 101 after the preset time.

The situation that the voltage platform of the voltage sampling point M has already been ended but the sampling voltage V2 output by the sampling output end OUT has not kept up with the voltage V1 of the voltage sampling point M can be avoided, thereby ensuring that the voltage sampling circuit can sample the voltage of the voltage inflection point.

According to an embodiment of the present disclosure, as shown in FIG. 4, the sampling and holding unit 101 further comprises: a first resistor R1, a first capacitor C1, a second resistor R2, and a second capacitor C2, wherein the first end of the first resistor R1 is connected with the voltage sampling point M, the second end of the first resistor R1 is connected with one end of the transmission gate TR, and the control end of the transmission gate TR is connected with the controller 20; one end of the first capacitor C1 is connected with the other end of the transmission gate TR, the other end of the first capacitor C1 is grounded, and a first node is formed between the first capacitor C1 and the transmission gate TR; the first end of the second resistor R2 is connected with the first node, and the second end of the second resistor R2 is connected with the controller 20; and one end of the second capacitor C2 is connected with the second end of the second resistor R2, the other end of the second capacitor C2 is grounded, and a second node is formed between the second capacitor C2 and the second resistor R2.

Specifically, the first resistor R1 and the first capacitor C1 can constitute a first-order RC filter circuit, and the second resistor R2 and the second capacitor C2 can constitute a second-order RC filter circuit. The first end of the first resistor R1 can serve as the sampling input end IN of the sampling and holding circuit 10, the control end of the transmission gate TR can serve as the sampling control end P of the sampling and holding circuit 10, the first node can serve as a first sampling output end OUT′ of the sampling and holding circuit 10, and the second node can serve as a second sampling output end OUT″ of the sampling and holding circuit 10. The sampling voltage can be output to an error amplifier of a switch power supply by means of the first sampling output end OUT′, and the sampling voltage can be output to the controller 20 by means of the second sampling output end OUT″.

It should be understood that the sampling voltage can also be output to the error amplifier of the switch power supply by means of the second sampling output end OUT″.

According to an embodiment of the present disclosure, as shown in FIG. 4, the switch unit 102 comprises: a first MOS transistor MOS1 and a second MOS transistor MOS2, wherein the source electrode S of the first MOS transistor MOS1 is respectively connected with the first end of the first resistor R1 and the voltage sampling point M, the drain electrode D of the first MOS transistor MOS1 is connected with the first node, and the grid electrode G of the first MOS transistor MOS1 is connected with the trigger unit 103; and the source electrode S of the second MOS transistor MOS2 is connected with the first node, the drain electrode D of the first MOS transistor MOS1 is connected with the second node, and the grid electrode G of the second MOS transistor MOS2 is respectively connected with the grid electrode G of the first MOS transistor MOS1 and the trigger unit 103.

According to an embodiment of the present disclosure, as shown in FIG. 4, the trigger unit 103 comprises a leading edge blanking circuit 110.

According to a specific embodiment of the present disclosure, as shown in FIG. 3, at the time t1, the voltage V1 of the voltage sampling point M is greater than the preset voltage V0 (such as 0.1V); during the time period from t1 to t3, the voltage waveform at the initial stage of the voltage platform of the voltage sampling point M has oscillation fluctuation, and then, the voltage platform of the voltage sampling point M has a slow downtrend; and at the time t3, the voltage of the voltage sampling point M has a fast downtrend, i.e., at the time t3, the voltage of the voltage sampling point M is in a voltage inflection point. In the embodiment of the present disclosure, sampling can be performed at the time t2, i.e., at the time t2, the delay unit 210 outputs a sampling signal to the setting end S of the trigger 201, the voltage sampling circuit enters the sampling stage to prevent the oscillation fluctuation from being sampled, and at this time, the preset delay time of the delay unit 210 is: T=t2−t1.

Specifically, at the time t1, the voltage V1 of the voltage sampling point M is greater than 0.1V, the first comparator CMP1 outputs a sampling signal (such as a high level), the delay unit 210 outputs the sampling signal to the setting end S of the trigger 201 at the time t2 as shown in FIG. 3, and the output of the trigger 201 is set high, namely the output end O of the trigger 201 outputs a switching-on control signal SH (such as a high level). The transmission gate TR is switched on when receiving the switching-on control signal SH so as to control the sampling and holding circuit 10 to enter the sampling stage. At the initial sampling stage, the trigger unit 103 receives the switching-on control signal SH to generate a trigger signal (such as a PWM signal SHFA with a tiny pulse), and the pulse width of the trigger signal SHFA is less than the pulse width of the switching-on control signal SH. When the PWM signal SHFA is a high level, the first MOS transistor MOS1 and the second MOS transistor MOS2 are switched on, and the switch unit 102 is switched on for a preset time so as to enable the transmission gate TR, the first resistor R1, the first capacitor C1, the second resistor R2 and the second capacitor C2 in the sampling and holding unit 101 to be short-circuited for a preset time. At this time, the sampling voltage V2 output by the sampling output end OUT does not pass through the RC filter circuit, and the sampling voltage V2 quickly follows the voltage V1 of the voltage sampling point M by means of the switch unit 102. When the voltage platform time of the voltage sampling point M is shorter, the situation that the voltage platform of the voltage sampling point M has already been ended but the sampling voltage V2 output by the sampling output end OUT has not kept up with the voltage V1 of the voltage sampling point M can be avoided, thereby ensuring that the voltage sampling circuit can sample the voltage of the voltage inflection point.

When the PWM signal SHFA is changed into a low level, the first MOS transistor MOS1 and the second MOS transistor MOS2 are switched off, and the sampling voltage V2 output by the sampling output end OUT follows the voltage V1 of the voltage sampling point M by means of the sampling and holding unit 101. Specifically, the transmission gate TR is switched on under the control of the switching-on control signal SH, the transmission gate TR and the first-order RC filter circuit process the voltage V1 of the voltage sampling point M and then output the sampling voltage V2 to the error amplifier of the switch power supply, and the transmission gate TR, the first-order RC filter circuit and the second-order RC filter circuit process the voltage V1 of the voltage sampling point M and then output the sampling voltage V2 to the first input end of the second comparator CMP2. Because the time constant of the RC filter circuit is larger, the change of the sampling voltage V2 output by the sampling output end OUT is later than the change of the voltage V1 of the voltage sampling point M.

During the time period from t2 to t3, the change of the voltage V1 of the voltage sampling point M is slower, the difference value between the sampling voltage V2 and the voltage V1 of the voltage sampling point M is less than the preset threshold value, the second comparator CMP2 outputs a first sampling end signal (such as a low level) to the resetting end R of the trigger 201, the trigger 201 holds the setting to continue to output a high level, the transmission gate TR is controlled to be switched on to perform continuous sampling, and the sampling voltage V2 follows the voltage V1 of the voltage sampling point M. If the change of the voltage V1 of the voltage sampling point M is larger, a difference value is generated between the sampling voltage V2 and the voltage V1 of the voltage sampling point M. At the time t3, the voltage V1 of the voltage sampling point M has a fast drop trend, i.e., the voltage V1 of the voltage sampling point M is in the voltage inflection point. At this time, the difference value between the sampling voltage V2 output by the sampling output end and the voltage V1 of the voltage sampling point M is greater than the preset threshold value, the second comparator CMP2 outputs a second sampling end signal (such as a high level) to the resetting end R of the trigger 201, the trigger 201 resets to output a low level, the transmission gate TR is controlled to be switched off so as to control the sampling stage to be ended to enter a holding stage, and the sampling voltage V2 is held at the voltage corresponding to the voltage inflection point.

In conclusion, according to the voltage sampling circuit provided by the embodiment of the present disclosure, the controller controls the sampling and holding circuit to enter the sampling stage when the voltage of the voltage sampling point is in the sampling voltage segment so as to enable the sampling voltage of the sampling output end to follow the voltage of the voltage sampling point, and controls the sampling stage of the sampling and holding circuit to be ended when the voltage of the voltage sampling point is in the voltage inflection point so as to enable the sampling voltage of the sampling output end to be held at the voltage corresponding to the voltage inflection point. Therefore, by sampling the voltage of the voltage inflection point, the magnitude of the output voltage can be accurately reflected, the influence on the sampling voltage caused by the load change of the switch power supply can be avoided, the stability and accuracy of the control system are improved, the constant voltage precision of the output voltage of the switch power supply is increased, and the user experience is promoted.

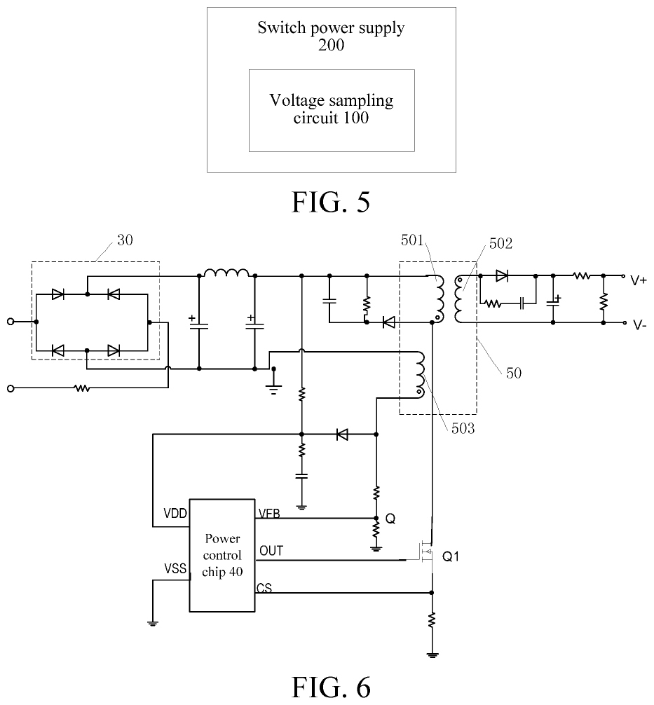

FIG. 5 is a block diagram of a switch power supply according to an embodiment of the present disclosure. As shown in FIG. 5, the switch power supply 200 comprises a voltage sampling circuit 100.

According to an embodiment of the present disclosure, as shown in FIG. 6, the switch power supply 200 comprises a rectification module 30, a power control chip 40, a power switch tube Q1, and a transformer component 50, wherein the voltage sampling circuit 100 is integrated in the power control chip 40; the transformer component 50 comprises a primary coil 501, a secondary coil 502, and a feedback coil 503; one end of the secondary coil 502 is connected with the first output end V+ of the switch power supply 200, and the other end of the secondary coil 502 is connected with the second output end V− of the switch power supply 200; one end of the feedback coil 503 is connected with the power control chip 40, and the other end of the feedback coil 503 is connected with the rectification module 30.

Specifically, the power control chip 40 is used for outputting a control signal to control the power switch tube Q1 (such as an MOS transistor) to be switched on or switched off so as to realize primary and secondary energy transfer of the transformer component 50, and the output voltage and output current of the secondary coil 502 are controlled by controlling the working frequency and switching-on duty ratio of the power switch tube Q 1 . The power control chip 40 is further used for sampling the output voltage of the secondary coil 502 by means of the feedback coil 503 so as to adjust the output frequency and duty ratio of the control signal, so as to enable the output voltage of the secondary coil 502 to be kept stable.

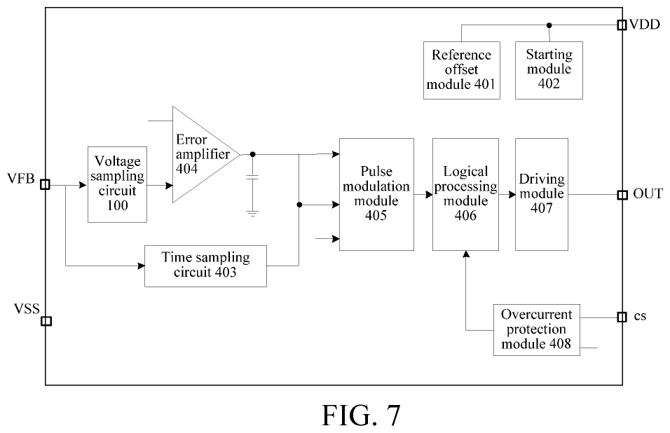

According to a specific embodiment of the present disclosure, as shown in FIG. 7, the power control chip 40 comprises the following ports: a power supply pin VDD, a grounding pin VSS, a current input pin CS, an output pin OUT, and a voltage feedback pin VFB, wherein the power supply pin VDD serves as a power supply end of the power control chip 40 so as to be used for supplying power to the control chip; the current input pin CS is used for detecting the current flowing through the primary coil of the transformer component 50; the output pin OUT is used for outputting a control signal so as to control the power switch tube Q1 to be switched on or switched off; and the sampling pin VFB is used for sampling the feedback voltage of the feedback coil, i.e., the voltage feedback pin VFB is the voltage sampling point of the voltage sampling circuit in the above embodiment.

In the embodiment of the present disclosure, as shown in FIG. 7, the power control chip 40 can further comprise: a reference offset module 401, a starting module 402, a time sampling circuit 403, an error amplifier 404, a pulse modulation module 405, a logical processing module 406, a driving module 407, and an overcurrent protection module 408.

The input end of the voltage sampling circuit 100 is connected with the voltage feedback pin VFB, and the output end (such as OUT' in the embodiment as shown in FIG. 4) of the voltage sampling circuit 100 is connected with the first input end of the error amplifier 404; the second input end of the error amplifier 404 is connected with a reference voltage supply end; the input end of the time sampling circuit 403 is connected with the voltage feedback pin VFB, the output end of the time sampling circuit 403 is connected with the output end of the error amplifier 404, and a third node is formed between the output end of the time sampling circuit 403 and the output end of the error amplifier 404; the first input end of the pulse modulation module 405 is connected with the third node, and the second input end of the pulse modulation module 405 is connected with the output end of the time sampling circuit 403; the first input end of the logical processing module 406 is connected with the output end of the pulse modulation module 405; the input end of the driving module 407 is connected with the output end of the logical processing module 406, and the output end of the driving module 407 is connected with the output pin OUT; and the first input end of the overcurrent protection module 408 is connected with the current input pin CS, the second input end of the overcurrent protection module 408 is connected with a reference current supply end, and the output end of the overcurrent protection module 408 is connected with the second input end of the logical processing module 406.

Specifically, the reference offset module 401 is used for supplying the voltage reference and current offset required in the power control chip 40; the starting module 402 is used for controlling the power control chip 40 to be started or stopped; the voltage sampling circuit 100 is used for sampling the voltage V1 of a feedback winding and outputting the sampling voltage V2; the time sampling circuit 403 is used for sampling the voltage platform time of the voltage sampling point so as to perform constant current control on the switch power supply; the error amplifier 404 is used for comparing the sampling voltage V2 with the reference voltage and performing error amplification; the pulse modulation module 405 is used for performing pulse width modulation and pulse frequency modulation, so as to output and convert an analog signal output by the error amplifier 404 into a PWM signal, and output the PWM signal to the logical processing module 406; the logical processing module 406 is used for logically processing the PWM signal so as to generate a corresponding control signal; the driving module 407 is used for generating a driving control signal so as to drive the power switch tube Q1; and the overcurrent protection module 408 is used for detecting the peak current of the primary current, and generating a power switch tube switching-off signal when the peak current of the primary current exceeds the preset current threshold so as to perform overcurrent protection on the switch power supply.

Thus, the switch power supply can sample the output voltage of the secondary coil by means of the feedback coil. The voltage sampling circuit generates the corresponding sampling voltage V2 according to the voltage V1 of the voltage sampling point M and outputs the sampling voltage V2 to the error amplifier, and the error amplifier 404 processes the sampling voltage V2, adjusts the whole system loop according to the sampling voltage V2, and adjusts the control signal output by the power control chip 40 according to the sampling voltage V2 so as to adjust the working frequency and switching-on duty ratio of the power switch tube Q1, so that the output voltage of the secondary coil is kept stable.

In conclusion, according to the switch power supply provided by the embodiment of the present disclosure, by sampling the voltage of the voltage inflection point by means of the voltage sampling circuit, the magnitude of the output voltage can be accurately reflected, the influence on the sampling voltage caused by the load change of the switch power supply can be avoided, the stability and accuracy of the control system are improved, the constant voltage precision of the output voltage of the switch power supply is increased, and the user experience is promoted.

In the description of the present disclosure, it should be understood that, orientations or position relationships indicated by terms such as “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, and “circumferential” are orientations or position relationship shown based on the accompanying drawings, and are merely used for describing the present disclosure and simplifying the description, rather than indicating or implying that the apparatus or element should have a particular orientation or be constructed and operated in a particular orientation, and therefore, should not be construed as a limitation on the present disclosure.

In addition, terms “first” and “second” are used only for description purposes, and shall not be understood as indicating or suggesting relative importance or implicitly indicating a quantity of indicated technical features. Therefore, features defined by “first” and “second” may explicitly or implicitly include at least one feature. In the description of the present disclosure, unless otherwise specifically limited, “multiple” means at least two, for example, two or three.

In the present disclosure, it should be noted that unless otherwise clearly specified and limited, the terms “mounted”, “connected”, “connection”, and “fixed” should be understood in a broad sense. For example, a connection may be a fixed connection, a detachable connection, or an integral connection; may be a mechanical connection or an electrical connection; may be a direct connection or an indirect connection by means of an intermediate medium; or may be internal communication between two elements or interaction relationship between two elements, unless otherwise clearly limited. A person of ordinary skill in the art may understand specific meanings of the terms in the present disclosure according to specific situations.

In the present disclosure, unless explicitly specified or limited otherwise, a first characteristic “on” or “under” a second characteristic may be the first characteristic in direct contact with the second characteristic, or the first characteristic in indirect contact with the second characteristic by using an intermediate medium. Moreover, that the first feature is “above”, “over”, and “on” the second feature may be that the first feature is right above the second feature or at an inclined top of the second feature, or may merely indicate that the horizontal height of the first feature is higher than that of the second feature. That the first feature is “below”, “under”, and “beneath” the second feature may be that the first feature is right below the second feature or at an inclined bottom of the second feature, or may merely indicate that the horizontal height of the first feature is lower than that of the second feature.

In the descriptions of this specification, a description of a reference term such as “an embodiment”, “some embodiments”, “an example”, “a specific example”, or “some examples” means that a specific feature, structure, material, or characteristic that is described with reference to the embodiment or the example is included in at least one embodiment or example of the present disclosure. In this specification, exemplary descriptions of the foregoing terms do not necessarily refer to a same embodiment or example. In addition, the described specific features, structures, materials, or characteristics may be combined in a proper manner in any one or more of the embodiments or examples. In addition, a person skilled in the art may integrate or combine different embodiments or examples and characteristics of different embodiments or examples described in the specification, as long as they do not conflict each other.

Although the embodiments of the present disclosure are shown and described above, it can be understood that, the foregoing embodiments are exemplary, and cannot be construed as a limitation to the present disclosure. Within the scope of the present disclosure, a person of ordinary skill in the art may make changes, modifications, replacement, and variations to the foregoing embodiments.

What is claimed is:

1. A voltage sampling circuit, comprising:
a sampling and holding circuit, comprising a sampling input end, a sampling output end, and a sampling control end, wherein the sampling input end is connected with a voltage sampling point, and the sampling and holding circuit is configured to sample a voltage of the voltage sampling point in a sampling stage so as to enable a sampling voltage of the sampling output end to follow the voltage of the voltage sampling point, and holding the sampling voltage of the sampling output end after the sampling stage is ended; and
a controller, wherein the controller is respectively connected with the voltage sampling point, the control end and the sampling output end of the sampling and holding circuit, and the controller configured to control the sampling and holding circuit to enter the sampling stage when determining that the voltage of the voltage sampling point is in a sampling voltage segment according to the voltage of the voltage sampling point, and to control the sampling stage of the sampling and holding circuit to be ended when determining that the voltage of the voltage sampling point is in a voltage inflection point according to the voltage of the voltage sampling point and the sampling voltage of the sampling output end, so as to enable the sampling voltage of the sampling output end to be held at the voltage corresponding to the voltage inflection point.

2. The voltage sampling circuit according to claim 1, wherein the controller comprises:
a trigger, wherein the trigger comprises a setting end, a resetting end, and an output end, and the output end of the trigger is connected with the sampling control end of the sampling and holding circuit;
a first controller, wherein an input end of the first controller is connected with the voltage sampling point, an output end of the first controller is connected with the setting end of the trigger, and the first controller configured to control the setting of the trigger to control the sampling and holding circuit to enter the sampling stage when determining that the voltage of the voltage sampling point is in a sampling voltage segment; and
a second controller, wherein an input end of the second controller is connected with the voltage sampling point and the sampling output end, an output end of the second controller is connected with the resetting end of the trigger, and the second controller is configured to control the resetting of the trigger to control the sampling stage of the sampling and holding module to be ended when determining that the voltage of the voltage sampling point is in the voltage inflection point.

3. The voltage sampling circuit according to claim 2, wherein the first controller comprises:
a first comparator, wherein a first input end of the first comparator is connected with the voltage sampling point, a second input end of the first comparator is connected with a preset voltage supply end, and the first comparator is configured to output a sampling signal when the voltage of the voltage sampling point is greater than a preset voltage; and
a delay circuit, wherein one end of the delay circuit is connected with the output end of the first comparator, the other end of the delay circuit is connected with the setting end of the trigger, and the delay circuit is configured to delay the sampling signal for a preset delay time and then to output the sampling signal to the trigger so as to control the setting of the trigger.

4. The voltage sampling circuit according to claim 2, wherein the second controller comprises:
a second comparator, wherein a first input end of the second comparator is connected with the sampling output end, a second input end of the second comparator is connected with the voltage sampling point, an output end of the second comparator is connected with the resetting end of the trigger, and the second comparator is configured to output a sampling end signal to the trigger so as to control the resetting of the trigger when a difference value between the sampling voltage output by the sampling output end and the voltage of the voltage sampling point is greater than a preset threshold value.

5. The voltage sampling circuit according to claim 1, wherein the sampling and holding circuit comprises:
a sampling and holding unit, wherein the sampling and holding unit is respectively connected with the voltage sampling point and the controller, the sampling and holding unit comprises a transmission gate, and the controller controls the sampling and holding circuit to enter the sampling stage by controlling the transmission gate to be switched on, and controls the sampling stage to be ended by controlling the transmission gate to be switched off;
a switch unit, wherein the switch unit is connected with the sampling and holding unit in parallel, and the switch unit is controlled by a trigger unit; and
the trigger unit, wherein the trigger unit is respectively connected with the controller and the switch unit, and the trigger unit is configured to generate a trigger signal when the sampling and holding circuit enters the sampling stage to trigger the switch unit to be switched on for a preset time, so as to enable the output end of the sampling and holding circuit to firstly follow the voltage of the voltage sampling point by of the switch unit and then to follow the voltage of the voltage sampling point by of the sampling and holding unit after the preset time.

6. The voltage sampling circuit according to claim 5, wherein the sampling and holding unit further comprises:
a first resistor, wherein a first end of the first resistor is connected with the voltage sampling point, a second end of the first resistor is connected with one end of the transmission gate, and the control end of the transmission gate is connected with the controller;
a first capacitor, wherein the first capacitor is connected with the other end of the transmission gate, the other end of the first capacitor is grounded, and a first node is formed between the first capacitor and the transmission gate;
a second resistor, wherein a first end of the second resistor is connected with the first node, and a second end of the second resistor is connected with the controller; and
a second capacitor, wherein one end of the second capacitor is connected with the second end of the second resistor, the other end of the second capacitor is grounded, and a second node is formed between the second capacitor and the second resistor.

7. The voltage sampling circuit according to claim 6, wherein the switch unit comprises:
a first MOS transistor, wherein a source electrode of the first MOS transistor is respectively connected with the first end of the first resistor and the voltage sampling point, a drain electrode of the first MOS transistor is connected with the first node, and a grid electrode of the first MOS transistor is connected with the trigger unit; and
a second MOS transistor, wherein a source electrode of the second MOS transistor is connected with the first node, a drain electrode of the first MOS transistor is connected with the second node, and a grid electrode of the second MOS transistor is respectively connected with the grid electrode of the first MOS transistor and the trigger unit.

8. The voltage sampling circuit according to claim 5, wherein the trigger unit comprises a leading edge blanking circuit.

9. A switch power supply, comprising the voltage sampling circuit according to claim 1.

10. The voltage sampling circuit according to claim 3, wherein the second controller comprises:
a second comparator, wherein a first input end of the second comparator is connected with the sampling output end, a second input end of the second comparator is connected with the voltage sampling point, an output end of the second comparator is connected with the resetting end of the trigger, and the second comparator is configured to output a sampling end signal to the trigger so as to control the resetting of the trigger when a difference value between the sampling voltage output by the sampling output end and the voltage of the voltage sampling point is greater than a preset threshold value.

11. The voltage sampling circuit according to claim 2, wherein the sampling and holding circuit comprises:
a sampling and holding unit, wherein the sampling and holding unit is respectively connected with the voltage sampling point and the controller, the sampling and holding unit comprises a transmission gate, and the controller controls the sampling and holding circuit to enter the sampling stage by controlling the transmission gate to be switched on, and controls the sampling stage to be ended by controlling the transmission gate to be switched off;
a switch unit, wherein the switch unit is connected with the sampling and holding unit in parallel, and the switch unit is controlled by a trigger unit; and
the trigger unit, wherein the trigger unit is respectively connected with the controller and the switch unit, and the trigger unit is configured to generate a trigger signal when the sampling and holding circuit enters the sampling stage to trigger the switch unit to be switched on for a preset time, so as to enable the output end of the sampling and holding circuit to firstly follow the voltage of the voltage sampling point by the switch unit and then to follow the voltage of the voltage sampling point by the sampling and holding unit after the preset time.

12. The voltage sampling circuit according to claim 3, wherein the sampling and holding circuit comprises:
a sampling and holding unit, wherein the sampling and holding unit is respectively connected with the voltage sampling point and the controller, the sampling and holding unit comprises a transmission gate, and the controller controls the sampling and holding circuit to enter the sampling stage by controlling the transmission gate to be switched on, and controls the sampling stage to be ended by controlling the transmission gate to be switched off;
a switch unit, wherein the switch unit is connected with the sampling and holding unit in parallel, and the switch unit is controlled by a trigger unit; and
the trigger unit, wherein the trigger unit is respectively connected with the controller and the switch unit, and the trigger unit is configured to generate a trigger signal when the sampling and holding circuit enters the sampling stage to trigger the switch unit to be switched on for a preset time, so as to enable the output end of the sampling and holding circuit to firstly follow the voltage of the voltage sampling point by the switch unit and then to follow the voltage of the voltage sampling point by the sampling and holding unit after the preset time.

13. The voltage sampling circuit according to claim 4, wherein the sampling and holding circuit comprises:
a sampling and holding unit, wherein the sampling and holding unit is respectively connected with the voltage sampling point and the controller, the sampling and holding unit comprises a transmission gate, and the controller controls the sampling and holding circuit to enter the sampling stage by controlling the transmission gate to be switched on, and controls the sampling stage to be ended by controlling the transmission gate to be switched off;
a switch unit, wherein the switch unit is connected with the sampling and holding unit in parallel, and the switch unit is controlled by a trigger unit; and
the trigger unit, wherein the trigger unit is respectively connected with the controller and the switch unit, and the trigger unit is configured to generate a trigger signal when the sampling and holding circuit enters the sampling stage to trigger the switch unit to be switched on for a preset time, so as to enable the output end of the sampling and holding circuit to firstly follow the voltage of the voltage sampling point by the switch unit and then to follow the voltage of the voltage sampling point by the sampling and holding unit after the preset time.

14. The voltage sampling circuit according to claim 10, wherein the sampling and holding circuit comprises:
a sampling and holding unit, wherein the sampling and holding unit is respectively connected with the voltage sampling point and the controller, the sampling and holding unit comprises a transmission gate, and the controller controls the sampling and holding circuit to enter the sampling stage by controlling the transmission gate to be switched on, and controls the sampling stage to be ended by controlling the transmission gate to be switched off;
a switch unit, wherein the switch unit is connected with the sampling and holding unit in parallel, and the switch unit is controlled by a trigger unit; and
the trigger unit, wherein the trigger unit is respectively connected with the controller and the switch unit, and the trigger unit is configured to generate a trigger signal when the sampling and holding circuit enters the sampling stage to trigger the switch unit to be switched on for a preset time, so as to enable the output end of the sampling and holding circuit to firstly follow the voltage of the voltage sampling point by the switch unit and then to follow the voltage of the voltage sampling point by the sampling and holding unit after the preset time.

15. The voltage sampling circuit according to claim 14, wherein the sampling and holding unit further comprises:
a first resistor, wherein a first end of the first resistor is connected with the voltage sampling point, a second end of the first resistor is connected with one end of the transmission gate, and the control end of the transmission gate is connected with the controller;
a first capacitor, wherein the first capacitor is connected with the other end of the transmission gate, the other end of the first capacitor is grounded, and a first node is formed between the first capacitor and the transmission gate;
a second resistor, wherein a first end of the second resistor is connected with the first node, and a second end of the second resistor is connected with the controller; and
a second capacitor, wherein one end of the second capacitor is connected with the second end of the second resistor, the other end of the second capacitor is grounded, and a second node is formed between the second capacitor and the second resistor.

16. The voltage sampling circuit according to claim 15, wherein the switch unit comprises:
a first MOS transistor, wherein a source electrode of the first MOS transistor is respectively connected with the first end of the first resistor and the voltage sampling point, a drain electrode of the first MOS transistor is connected with the first node, and a grid electrode of the first MOS transistor is connected with the trigger unit; and
a second MOS transistor, wherein a source electrode of the second MOS transistor is connected with the first node, a drain electrode of the first MOS transistor is connected with the second node, and a grid electrode of the second MOS transistor is respectively connected with the grid electrode of the first MOS transistor and the trigger unit.

17. The voltage sampling circuit according to claim 14, wherein the trigger unit comprises a leading edge blanking circuit.

18. A switch power supply, comprising the voltage sampling circuit according to claim 16.

19. A switch power supply, comprising the voltage sampling circuit according to claim 17.
